(19) United States
(12) Patent Application Publication
(10) Pub. No.: US 2024/0384388 A1
(43) Pub. Date: Nov. 21, 2024

(54) MASK AND DEPOSITION APPARATUS INCLUDING THE SAME

(71) Applicant: Samsung Display Co., LTD., Yongin-si (KR)

(72) Inventors: Duck Jung LEE, Yongin-si (KR); Jeong Kuk KIM, Yongin-si (KR); Sung Soon IM, Yongin-si (KR)

(21) Appl. No.: 18/435,058

(22) Filed: Feb. 7, 2024

(30) Foreign Application Priority Data
May 17, 2023 (KR) 10-2023-0064018

(51) Int. Cl. C23C 14/04

(52) U.S. Cl. CPC C23C 14/042

(57) ABSTRACT

A mask includes a body frame defining at least one opening arranged on a plane, at least one sub-mask overlapping the opening, and defining holes through which a deposition material is able to pass, and an aligner between the sub-mask and the body frame, and configured to move the sub-mask within the opening in response to applied voltages.

### CROSS-REFERENCE TO RELATED APPLICATION

The present application claims priority to, and the benefit of, Korean Patent Application No. 10-2023-0064018, filed May 17, 2023, in the Korean Intellectual Property Office, the entire disclosure of which is incorporated herein by reference.

### BACKGROUND

### 1. Field

The present disclosure relates to a mask and to a deposition apparatus including the same.

### 2. Description of the Related Art

As information technology develops, the importance of a display device, which is a connection medium between a user and information, has been emphasized.

In response to this, the use of display devices, such as a liquid crystal display device, an organic light-emitting display device, or the like, has been increasing.

As an example, the display device includes pixels. A light-emitting element included in each of the pixels may include electrodes spaced apart from each other and a light-emitting layer located between the electrodes.

Here, the electrodes and the light-emitting layer may be formed in various ways. Among them, an independent deposition method is a method in which a mask (for example, a fine metal mask (FMM)) is stretched and brought into close contact with a mask frame, and a deposition material is deposited on a surface of an object to be deposited.

The above description is only for helping the understanding of the background art for the technical ideas of the present disclosure. Therefore, it should not be understood as disclosing prior art known to those skilled in the art to which the present disclosure pertains.

### SUMMARY

A mask and a deposition apparatus including the same according to embodiments of the present disclosure are configured to perform a deposition process with improved reliability. For example, sub-masks of the mask may be finely adjusted to improve deposition quality. For example, the mask includes aligners that are capable of moving the sub-masks, and the deposition apparatus may control the aligners so that the sub-masks are respectively aligned at positions corresponding to portions of a substrate (e.g., predetermined portions of a substrate) on which a deposition material is to be deposited. Accordingly, the sub-masks may be accurately located at the positions corresponding to portions of a substrate (e.g., predetermined portions of a substrate) of the substrate, so that the deposition material may be deposited at desired positions.

A mask according to embodiments of the present disclosure may include a body frame defining at least one opening arranged on a plane, at least one sub-mask overlapping the opening, and defining holes through which a deposition material is able to pass, and an aligner between the sub-mask and the body frame, and configured to move the sub-mask within the opening in response to applied voltages.

The sub-mask may have a polygonal shape including sides, wherein the aligner includes actuators between the sides of the sub-mask and the body frame.

The sub-mask may include connecting parts protruding from the sides and contacting the actuators.

The actuators may include a first electrode contacting the body frame, a second electrode contacting the sub-mask, and a piezoelectric layer between the first electrode and the second electrode.

The piezoelectric layer may be configured to vibrate according to an applied voltage.

At least one of the actuators may have a shape configured to be changed by vibration of the piezoelectric layer, wherein the sub-mask is configured to be moved by the at least one of the actuators having the changed shape.

The sub-mask may be horizontally moved or rotated in a direction parallel to the plane by the at least one of the actuators having the changed shape.

In an area where the sub-mask and the body frame are spaced apart from each other in a first direction, the actuators may include a first actuator extending in a second direction crossing the first direction.

In an area where the sub-mask and the body frame are spaced apart from each other in the second direction, the actuators may include a second actuator extending in the first direction.

The first actuator may include a first portion, a second portion, and a third portion sequentially arranged in a direction opposite to the second direction, wherein the sub-mask includes a connecting part protruding from one of the sides in the first direction, and contacting the first portion, and wherein the body frame includes a fixing part protruding in a direction opposite to the first direction, and contacting the third portion.

The third portion may be fixed by the fixing part, wherein the first actuator is bent clockwise or counterclockwise around the third portion to move the sub-mask.

Another aspect of the present disclosure relates to a deposition apparatus. The deposition apparatus according to embodiments of the present disclosure may include a chamber, a deposition source inside the chamber, and configured to supply a deposition material, a support configured to fix a substrate on the deposition source, a mask including a body frame defining at least one opening arranged on a plane, at least one sub-mask overlapping the opening and defining holes through which the deposition material is able to pass, and an aligner between the sub-mask and the body frame and configured to move the sub-mask within the opening in response to applied voltages, and a mask frame supporting the mask.

The mask may include a first alignment mark, wherein the support includes a second alignment mark corresponding to the first alignment mark.

The deposition apparatus may further include a camera for capturing an image of the first and second alignment marks, and a processor for aligning a position of the sub-mask based on the image.

The deposition apparatus may further include a voltage applier for applying a voltage to the aligner according to a control signal generated by the processor.

### BRIEF DESCRIPTION OF THE DRAWINGS

The accompanying drawings, which are included to provide a further understanding of the present disclosure, and are incorporated in and constitute a part of this specification, illustrate embodiments of the present disclosure, and, together with the description, serve to explain aspects of the disclosure.

FIG. 1 is a diagram illustrating a deposition apparatus according to one or more embodiments of the present disclosure.

FIG. 2 is a perspective view illustrating one or more embodiments of a mask assembly of FIG. 1.

FIG. 3 is a cross-sectional view taken along the line I-I′ of FIG. 2.

FIG. 4 is a plan view illustrating a first area shown in FIG. 3.

FIG. 5 is a plan view illustrating a second area shown in FIG. 4.

FIG. 6 is a plan view illustrating actuators having shapes changed by an applied voltage.

FIG. 7 is a diagram illustrating movement of a sub-mask within an opening by the actuators having changed shapes.

FIG. 8 is a diagram illustrating one or more embodiments of alignment marks of a support and mask of FIG. 1.

FIG. 9 is a diagram illustrating first and second alignment marks that are not aligned with each other.

FIG. 10 is a block diagram illustrating a main controller configured to control the deposition apparatus of FIG. 1.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The present disclosure covers all modifications, equivalents, and replacements within the idea and technical scope of the present disclosure. Further, each of the features of the various embodiments of the present disclosure may be combined with each other, in part or in whole, and technically various interlocking and driving are possible. Each embodiment may be implemented independently of each other or may be implemented together in an association.

In the drawings, the relative sizes of elements and regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements or regions, but are to include deviations in shapes that result from, for instance, manufacturing.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, region, or component is referred to as being “formed on,” “on,” “connected to,” or “(operatively or communicatively) coupled to” another element, region, or component, it can be directly formed on, on, connected to, or coupled to the other element, region, or component, or indirectly formed on, on, connected to, or coupled to the other element, region, or component such that one or more intervening elements, regions, or components may be present. In addition, this may collectively mean a direct or indirect coupling or connection and an integral or non-integral coupling or connection. For example, when a region or component is referred to as being “electrically connected” or “electrically coupled” to another region or component, it can be directly electrically connected or coupled to the other region and/or component or intervening regions or components may be present. However, “directly connected/directly coupled,” or “directly on,” refers to one component directly connecting or coupling another component, or being on another component, without an intermediate component. It will be understood that when an element is referred to as being “between” two elements, it can be the only element between the two elements, or one or more intervening elements may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expression such as “at least one of A and B” and “at least one of A or B” may include A, B, or A and B. As used herein, “or” generally means “and/or,” and the term “and/or” includes any and all combinations of one or more of the associated listed items. For example, the expression such as “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

Some embodiments are described in the accompanying drawings in relation to functional block, unit, and/or module. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

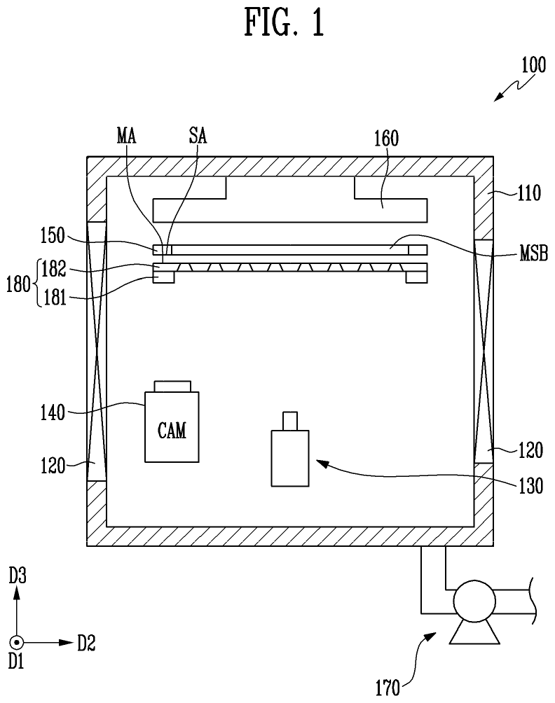

FIG. 1 is a diagram illustrating a deposition apparatus according to one or more embodiments of the present disclosure.

Referring to FIG. 1, a deposition apparatus 100 according to one or more embodiments may include a chamber 110, an opening/closing unit 120, a deposition source 130, a camera 140, a support 150, a magnetic force generator 160, a pressure controller 170, a mask assembly 180, and the like.

The chamber 110 may have an inner space. The inner space of the chamber 110 may be a workspace prepared for a deposition process. An object on which a deposition material is to be deposited may be accommodated (or located) inside the chamber 110. For example, a substrate MSB may be located inside the chamber 110.

The opening/closing unit 120 may be located on one side of the chamber 110. The substrate MSB may be inserted into the inner space of the chamber 110, or may be taken out of the chamber, through the open opening/closing unit 120. The opening/closing unit 120 may include a valve and the like. The opening/closing unit 120 may be selectively opened and closed by controlling the valve.

The deposition source 130 may be located inside the chamber 110. The deposition source 130 may store the deposition material, and may supply the stored deposition material to the inner space of the chamber 110. The deposition material may include a material for forming a pattern layer (e.g., a predetermined pattern layer, such as a light-emitting layer) on the substrate MSB. The deposition source 130 may vaporize or sublimate the deposition material by applying energy (for example, thermal energy, light energy, vibration energy, or the like) to the deposition material. As an example, the deposition source 130 may include a heater therein. As the deposition material inside the deposition source 130 is heated by the operation of the heater, the deposition material may be melted or sublimated. The deposition source 130 may be replaceable. The deposition source 130 may be replaced with a new deposition source if the stored deposition material is exhausted.

The camera 140 may be located inside the chamber 110 facing the mask assembly 180 and the substrate MSB to capture an image of them. For example, the camera 140 may capture an image of a support alignment area SA of the support 150 and a mask alignment area MA of a mask 182. The mask 182 may be aligned based on the captured image. The camera 140 may be any one of a variety of known cameras including a CCD (Charge-Coupled Device) camera.

The support 150 may support the substrate MSB. For example, the substrate MSB may be seated on the support 150 so that the support 150 may support the substrate MSB. For example, the support 150 may adsorb or attach one surface of the substrate MSB to support the substrate MSB. For example, the support 150 may include a clamp for gripping the substrate MSB. For example, the support 150 may include a sticky chuck or an electrostatic chuck. In this case, the support 150 may be integrally formed with the magnetic force generator 160. The support 150 may adjust the position of the substrate MSB. For example, the support 150 may include a UVW stage. The support 150 may be moved up and down (for example, raised and/or lowered) inside the chamber 110. In this case, a distance between the substrate MSB and the mask assembly 180 may be adjusted by the support 150. The support 150 may include the support alignment area SA. The support alignment area SA may be formed to correspond to the mask alignment area MA.

The magnetic force generator 160 may be located inside the chamber 110. The magnetic force generator 160 may move the mask 182 so that the mask 182 approaches (for example, adheres to) the substrate MSB. The magnetic force generator 160 may include an electromagnet, a permanent magnet, or the like that is configured to generate magnetic force.

The pressure controller 170 may be connected to the chamber 110 to adjust the pressure inside the chamber 110. The pressure controller 170 may include a pipe connected to the chamber 110, and a pump located in the pipe. In this case, the pump may adjust the pressure inside the chamber 110 through the pipe.

The mask assembly 180 may be located between the substrate MSB and the deposition source 130. The mask assembly 180 may include a mask frame 181 and the mask 182.

The mask frame 181 may support the mask 182. As an example, the mask 182 may be fixed to the mask frame 181 while being stretched in a first direction (for example, a longitudinal direction). The mask frame 181 may include a global opening through which the deposition material may pass.

For example, the mask 182 may be fixed to the mask frame 181 in a state in which tensile force is applied in one direction. The mask 182 may include at least one opening. The opening of the mask 182 may overlap the global opening of the mask frame 181.

The mask 182 may include the mask alignment area MA. The mask alignment area MS may be formed outside the mask 182. For example, the mask alignment area MA may be formed to overlap the mask frame 181. However, embodiments are not limited thereto, and the mask alignment area MA may be freely formed on the mask 182.

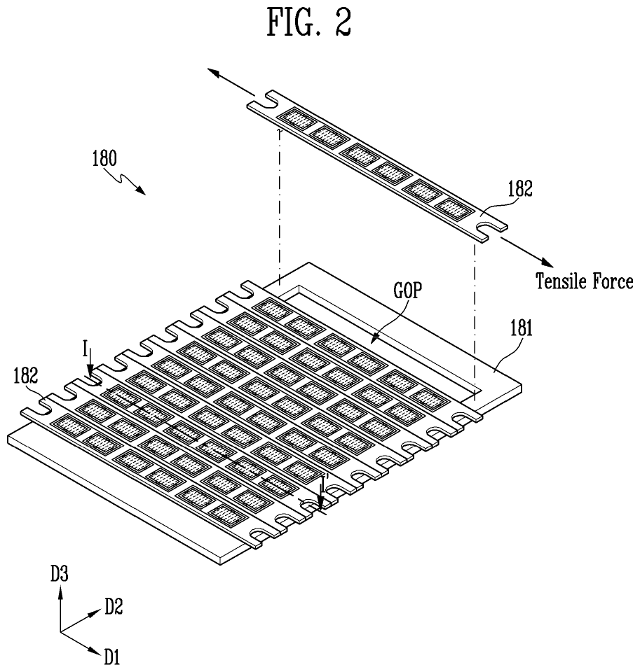

FIG. 2 is a perspective view illustrating one or more embodiments of a mask assembly of FIG. 1.

As shown in FIG. 2, the mask frame 181 may have a rectangular shape on a plane. However, embodiments are not limited thereto. As an example, the mask frame 181 may have various shapes, such as a polygon (e.g., a triangle or a pentagon), a circle, or an ellipse.

As shown in FIG. 2, the global opening GOP may have a rectangular shape on a plane. However, embodiments are not limited thereto. As an example, the global opening GOP may have various shapes, such as a polygon (e.g., a triangle or a pentagon), a circle, or an ellipse.

A thickness of the mask frame 181 may be relatively very thin compared to a length in a first direction D1 or a length in a second direction D2. If the thickness of the mask frame 181 is unsuitably thick, the deposition material may be restricted from passing through the mask 182 in a deposition process using the mask assembly 180. Conversely, if the thickness of the mask frame 181 is too thin, it may be difficult to secure rigidity for supporting the mask 182. The mask frame 181 may have an appropriate thickness in consideration of the above points.

The mask frame 181 may be made of a metal. For example, the mask frame 181 may be made of a metal that is not significantly deformed by welding.

The mask 182 may be a fine metal mask (FMM) used to deposit R, G, and B pixels on the substrate. Accordingly, the mask 182 may be made of materials widely used in manufacturing the fine metal mask (FMM). For example, the mask 182 may be made of stainless steel, invar, nickel (Ni), cobalt (Co), a nickel alloy, a nickel-cobalt alloy, or the like. The materials described above may have a relatively low coefficient of thermal expansion. Accordingly, a phenomenon in which the mask 182 is deformed by heat in a process of manufacturing the mask 182 can be alleviated.

A width (for example, length in the second direction D2) of the mask 182 may be smaller than a width (for example, length in the second direction D2) of the global opening GOP. As such, the mask 182 may be provided as a plurality of masks repeatedly arranged on the mask frame 181. For example, the plurality of masks may be arranged in the second direction D2. The plurality of masks may cover the global opening GOP.

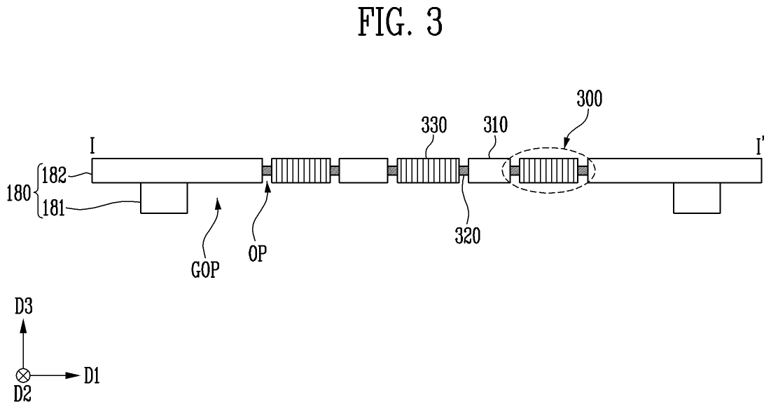

FIG. 3 is a cross-sectional view taken along the line I-I′ of FIG. 2.

Referring to FIG. 3, the mask 182 may include a body frame 310, an aligner 320, and a sub-mask 330.

The body frame 310 may be fixed to the mask frame 181 in a state in which tensile force is applied in the first direction D1. The body frame 310 may include a plurality of openings OP. The plurality of openings OP of the body frame 310 may exist within a range overlapping the global opening GOP.

The body frame 310 may be in contact with the aligner 320 to support the aligner 320. The body frame 310 may include the same material as that of the mask 182 described with reference to FIG. 2.

The aligner 320 and the sub-mask 330 may overlap an opening OP. The aligner 320 may be located between the body frame 310 and the sub-mask 330. A thickness (for example, length in a third direction D3) of the aligner 320 may be smaller than a thickness (for example, lengths in the third direction D3) of the body frame 310 and the sub-mask 330.

The aligner 320 may move the sub-mask 330 within the opening OP in response to an applied voltage. For example, the aligner 320 may include a piezoelectric actuator using an inverse piezoelectric effect. Accordingly, the aligner 320 may precisely move the sub-mask 330 within the opening OP.

The sub-mask 330 may be located to overlap the opening OP. A plurality of sub-masks may be located within the mask 182. The sub-mask 330 may correspond to a portion (for example, a pixel) of the substrate MSB on which the deposition material is to be deposited.

The sub-mask 330 may be made of the same material as the mask 182 described above. In addition, the sub-mask 330 may be composed of a bi-layer consisting of a semiconductor, such as silicon (Si) and/or silicon dioxide (SiO₂), an insulator, a metal, such as molybdenum (Mo) and/or titanium (Ti), or a combination thereof. Among the materials described above, because molybdenum (Mo), titanium (Ti), and the like have conductivity, the mask 182 may be adsorbed to the substrate MSB by an electrostatic chuck included in the support 150.

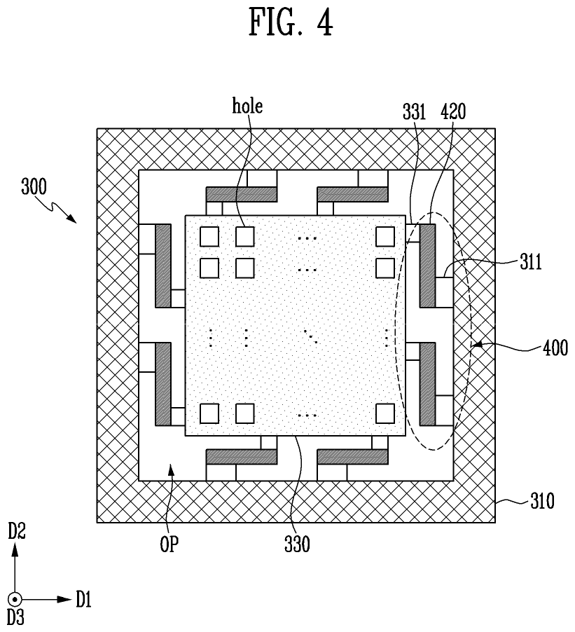

FIG. 4 is a plan view illustrating a first area shown in FIG. 3.

Referring to FIG. 4, the mask 182 according to one or more embodiments may include a fixing part 311, a connecting part 331, and an actuator 420.

A first area 300 may be an area including one sub-mask 330 located in the mask 182 of FIG. 3 and its periphery.

The fixing part 311 may be located to overlap the opening OP. The fixing part 311 may protrude from the body frame 310 in the first direction D1 and/or in a direction opposite to the first direction D1. The fixing part 311 may be made of the same material as the body frame 310. The fixing part 311 may be in contact with one surface of the actuator 420 to fix (e.g., hold or immobilize) the actuator 420.

In the fixing part 311 referenced in FIG. 4, a length of a side parallel to the first direction D1 may be shorter than a length of a side parallel to the second direction D2. Accordingly, the fixing part 311 may stably fix the actuator 420, which can have a changed shape. However, this is only an example, and the shape of the fixing part 311 is not limited thereto. The fixing part 311 may have various shapes as long as it can fix the actuator 420.

The sub-mask 330 may include one or more holes. For example, the hole may have any one of various shapes, such as a rectangle, a circle, and a square. In some embodiments, the sub-mask 330 may be provided as a fine metal mask (FMM).

An arrangement of a plurality of holes may form a pattern (e.g., predetermined pattern). The deposition material may be deposited only on a portion (for example, a pixel) of the substrate MSB by the formed pattern.

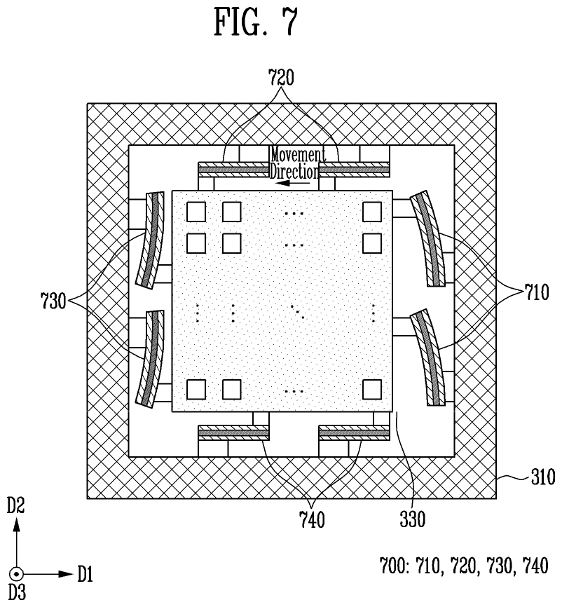

The sub-mask 330 may be moved and rotated within the opening OP by the actuator 420 whose shape is changed. This will be described in detail with reference to FIG. 7.

The connecting part 331 may be located to overlap the opening OP. The connecting part 331 referenced in FIG. 4 may protrude from the sub-mask 330 in the first direction D1, and may contact the actuator 420. The connecting part 331 may be made of the same material as the sub-mask 330.

The actuator 420 may overlap the opening OP, and may be located between the body frame 310 and the sub-mask 330. The actuator 420 may be connected to the body frame 310 through the fixing part 311, and may be connected to the sub-mask 330 through the connecting part 331.

The actuator 420 may be a flexural displacement type actuator, such as a Bi-morph actuator or a Uni-morph actuator. However, this is only an example, and the actuator 420 may be any one of driving elements capable of moving the sub-mask 330 within the opening OP.

A plurality of actuators may be located in the mask 182. Shapes of the plurality of actuators may be changed according to the applied voltage. Accordingly, the plurality of actuators may move the sub-mask 330 connected through the connecting part 331.

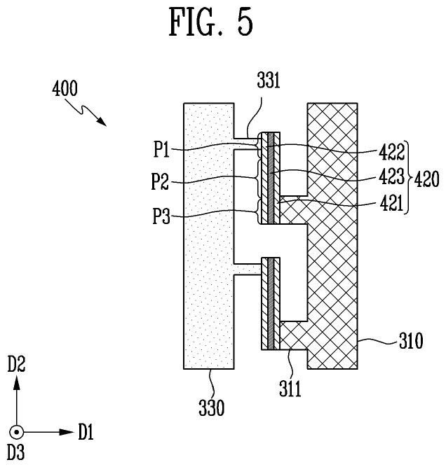

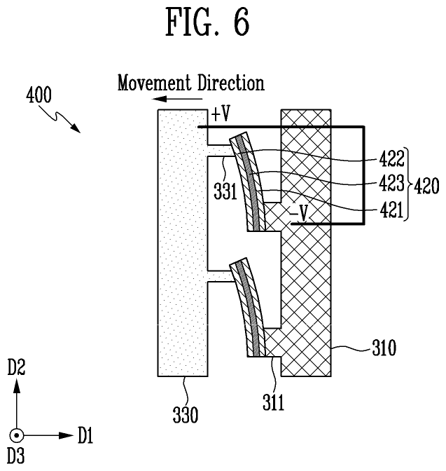

FIG. 5 is a plan view illustrating a second area shown in FIG. 4. FIG. 6 is a plan view illustrating actuators having shapes changed by an applied voltage.

First, referring to FIG. 5, in a second area 400 of FIG. 4, each actuator 420 may be located between the fixing part 311 and the connecting part 331. The actuator 420 may include a first electrode 421, a second electrode 422, and a piezoelectric layer 423.

The actuator 420 may include, for example, a first portion P1, a second portion P2, and a third portion P3 sequentially arranged in a direction opposite to the second direction D2.

The first electrode 421 may contact the fixing part 311 at the third portion P3. The second electrode 422 may contact the connecting part 331 at the first portion P1.

The first electrode 421 and the second electrode 422 may be made of a material widely used as an electrode material. As described above, the fixing part 311 may be made of a material having electrical conductivity. Accordingly, for example, if a negative voltage is applied to the body frame 310 and a positive voltage is applied to the second electrode 422, the first electrode 421 and the second electrode 422 may be a cathode and an anode, respectively.

The piezoelectric layer 423 may be formed of barium titanate (BaTiO₃), lead titanate (PbTiO₃), and lead zirconate (PbZrO₃) as well as piezoelectric ceramic (PZT) produced by mixing each of them in a ratio (e.g., a predetermined ratio). In addition, the piezoelectric layer 423 may be made of a polymeric piezoelectric material, such as EAP (Electro Active Polymer). Alternatively, the material constituting the piezoelectric layer 423 is not limited to the above materials, and may be made of materials capable of generating an inverse piezoelectric effect.

The piezoelectric layer 423 may be located between the first electrode 421 and the second electrode 422. The piezoelectric layer 423 may vibrate by an applied voltage. A potential difference may be generated between one side of the piezoelectric layer 423 in contact with the first electrode 421 and the other side of the piezoelectric layer 423 in contact with the second electrode 422 due to the applied voltage. In this case, positive ions of the material constituting the piezoelectric layer 423 may be pulled in a direction of the electric field formed by the potential difference, and negative ions of the material constituting the piezoelectric layer 423 may be pulled in an opposite direction. Accordingly, stress may be generated to deform the crystal lattice of the material constituting the piezoelectric layer 423, and thus, the piezoelectric layer 423 may vibrate. As the piezoelectric layer 423 vibrates in this way, the piezoelectric layer 423 may be bent. For example, the piezoelectric layer 423 may be bent clockwise or counterclockwise around the third portion P3 of the actuator 420.

The piezoelectric layer 423 may be bent toward a point having a high potential. As shown in FIG. 6, a negative voltage may be applied to the first electrode 421 through the fixing part 311, and a positive voltage may be applied to the second electrode 422 through the connecting part 331. For example, a terminal for applying a negative voltage to the fixing part 311 and/or a portion of the body frame 310 adjacent to the first electrode 421 may be provided, and a terminal for applying a positive voltage to the connecting part 331 and/or a portion of the sub-mask 330 adjacent to the second electrode 422 may be provided. In this case, for example, if the piezoelectric layer 423 is made of a polymeric piezoelectric material, such as EAP (Electro Active Polymer), positive and negative ions of the material constituting the piezoelectric layer 423 may move. Accordingly, to achieve internal equilibrium, water (H₂O) molecules inside the piezoelectric layer 423 may migrate to a region with many positive ions. Accordingly, the piezoelectric layer 423 may be bent in a direction (for example, counterclockwise direction) to which the positive voltage is applied.

FIG. 7 is a diagram illustrating movement of a sub-mask within an opening by the actuators having changed shapes.

Referring to FIG. 7, a plurality of actuators 700 may include first actuators 710, second actuators 720, third actuators 730, and fourth actuators 740.

The first actuators 710 may be arranged in the second direction D2 crossing the first direction D1 in an area where the body frame 310 and the sub-mask 330 are spaced apart from each other in the first direction D1.

The second actuators 720 may be arranged in the first direction D1 in an area where the body frame 310 and the sub-mask 330 are spaced apart from each other in the second direction D2.

The third actuators 730 may be adjacent to a surface that is opposite to a surface of the sub-mask 330 that is adjacent to the first actuators 710. The third actuators 730 may be arranged in the second direction D2 in an area where the body frame 310 and the sub-mask 330 are spaced apart from each other in the first direction D1. The third actuators 730 may be arranged to be reversed compared to the first actuators 710 based on a direction parallel to the first direction D1. For example, each of the first actuators 710 may contact the fixing part 311 at a lower side of a corresponding first actuator, and may contact the connecting part 331 at an upper side of the corresponding first actuator. Compared to this, each of the third actuators 730 may contact the fixing part 311 at an upper side of a corresponding third actuator, and may contact the connecting part 331 at a lower side of the corresponding third actuator.

The fourth actuators 740 may be adjacent to a surface that is opposite to a surface of the sub-mask 330 that is adjacent to the second actuators 720. The fourth actuators 740 may be arranged in the first direction D1 in an area where the body frame 310 and the sub-mask 330 are spaced apart from each other in the second direction D2. The fourth actuators 740 may be arranged to be reversed compared to the second actuators 720 based on a direction parallel to the second direction D2. For example, each of the second actuators 720 may contact the fixing part 311 at a lower side of a corresponding second actuator 720, and may contact the connecting part 331 at an upper side of the corresponding second actuator 720. Compared to this, each of the fourth actuators 740 may contact the fixing part 311 at an upper side of a corresponding fourth actuator 740, and may contact the connecting part 331 at a lower side of the corresponding fourth actuator 740.

Through such a structure of the plurality of actuators 700, the sub-mask 330 can be finely adjusted within the opening OP. However, this is only an example, and the shape of the plurality of actuators 700 is not limited thereto.

According to changes in the shape of the first actuators 710, the second actuators 720, the third actuators 730, and the fourth actuators 740, the sub-mask 330 may move within the opening OP.

As described with reference to FIG. 6, if a negative voltage is applied to each of the first actuators 710 through the body frame 310 and a positive voltage is applied through the sub-mask 330, and at the same time, if a positive voltage is applied to each of the third actuators 730 through the body frame 310 and a negative voltage is applied through the sub-mask 330, the sub-mask 330 may move in a direction opposite to the first direction D1 within the opening OP. For example, if the first actuators 710 are bent counterclockwise around a portion in contact with the fixing part 311, the third actuators 730 are bent clockwise around a portion in contact with the fixing part 311, and the shapes of the second and fourth actuators 720 and 740 do not change, then the sub-mask 330 may move in a direction opposite to the first direction D1.

A case where the sub-mask 330 moves in a direction opposite to the first direction D1 has been described with reference to FIG. 7, but embodiments are not limited thereto. For example, if a positive voltage is applied to each of the first actuators 710 through the body frame 310 and a negative voltage is applied through the sub-mask 330, and at the same time, if a negative voltage is applied to each of the third actuators 730 through the body frame 310 and a positive voltage is applied through the sub-mask 330, then the sub-mask 330 may move in the first direction D1 within the opening OP. In addition, by applying voltages to the plurality of actuators 700 in various ways, the sub-mask 330 may move in various directions within the opening OP. For example, by controlling the plurality of actuators 700, the sub-mask 330 may rotate clockwise or counterclockwise.

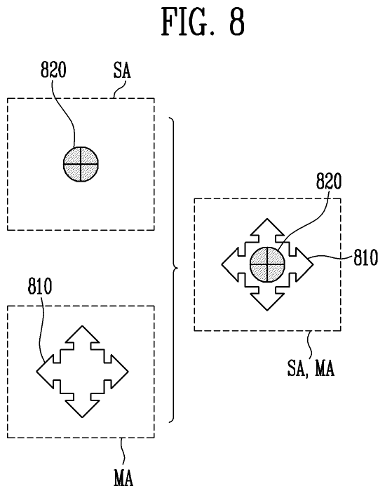

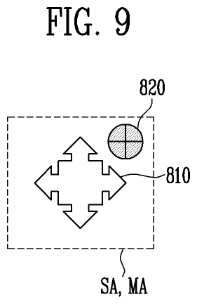

FIG. 8 is a diagram illustrating one or more embodiments of alignment marks of a support and mask of FIG. 1, and FIG. 9 is a diagram illustrating first and second alignment marks that are not aligned with each other.

Referring to FIG. 8, the mask alignment area MA may include a first alignment mark 810, and the support alignment area SA may include a second alignment mark 820.

The first alignment mark 810 may be provided in the mask alignment area MA. For example, the first alignment mark 810 may have a rectangular shape with arrows on all sides. However, this is only an example, and the first alignment mark 810 may have various shapes if it can be compared in position with the second alignment mark 820.

The second alignment mark 820 may be provided in the support alignment area SA. For example, the second alignment mark 820 may have a circular shape having a lattice shape therein. However, this is only an example, and the second alignment mark 820 may have various shapes if it can be compared in position with the first alignment mark 810.

Referring back to FIG. 1, the camera 140 may capture an image of the first alignment mark 810 and the second alignment mark 820.

The first alignment mark 810 and the second alignment mark 820 may be used to check whether the substrate MSB and the mask 182 are successfully (accurately) aligned. For example, the center of the lattice shape of the second alignment mark 820 may be accurately positioned at the center of the first alignment mark 810. In this case, it can be said that the first alignment mark 810 and the second alignment mark 820 are successfully aligned. Accordingly, it can be confirmed that the mask 182 is successfully aligned with respect to the substrate MSB.

Referring to FIG. 9, a case in which the first alignment mark and the second alignment mark are not accurately aligned may be confirmed. For example, if the first alignment mark 810 and the second alignment mark 820 do not overlap each other, it can be confirmed that the mask 182 is not successfully aligned with respect to the substrate MSB.

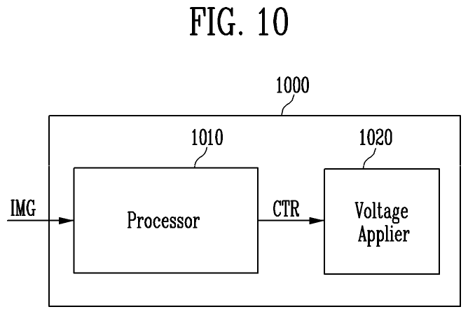

FIG. 10 is a block diagram illustrating a main controller configured to control the deposition apparatus of FIG. 1.

Referring to FIG. 10, a main controller 1000 may include a processor 1010 and a voltage applier 1020.

The processor 1010 may receive an image IMG captured by the camera 140. For example, the processor 1010 may determine whether the mask 182 is successfully aligned with respect to the substrate MSB based on the captured image IMG. For example, the processor 1010 may determine whether the sub-masks 330 (refer to FIG. 3) are accurately positioned to correspond to a portion (for example, a pixel) of the substrate MSB.

The processor 1010 may control the plurality of sub-masks based on the determined positions of the plurality of sub-masks. When it is determined that the plurality of sub-masks are not located at correct positions, the processor 1010 may generate a control signal CTR for moving each of the plurality of sub-masks so that the plurality of sub-masks may be aligned at a position (e.g., a predetermined position). The processor 1010 may supply the generated control signal CTR to the voltage applier 1020.

The voltage applier 1020 may apply voltages to the aligner 320 in response to the received control signal CTR. The voltage applier 1020 may apply voltages to the plurality of actuators 700 (refer to FIG. 7). As such, the voltage applier 1020 may generate a potential difference between the first electrode 421 and the second electrode 422 of each actuator. The corresponding sub-mask may be moved within the opening OP by the actuator whose shape is changed according to the generated potential difference.

The processor 1010 may finely change the voltage applied to the actuator by controlling the voltage applier 1020. The actuator may be changed to have a different shape according to the finely changed voltage. In other words, the degree of bending of the actuator may vary slightly in response to the changed voltage. Accordingly, the sub-mask 330 can be precisely aligned.

As such, the processor 1010 may control the voltage applier 1020 to move and/or rotate each of the plurality of sub-masks within the opening OP. Accordingly, the plurality of sub-masks may be precisely aligned with the substrate individually.

According to the embodiments of the present disclosure, a mask configured to perform a deposition process with improved reliability, and a deposition apparatus including the same, are provided.

Aspects according to the embodiments are not limited by the above-described contents, and more various other effects are included in the present specification. Although specific embodiments and implementations have been described herein, other embodiments and modifications may be derived from the foregoing descriptions. Accordingly, the spirit of the present disclosure is not limited to the foregoing embodiments, but may also be applied to the claims set forth below, various obvious modifications, and equivalents.

What is claimed is:

1. A mask comprising:
a body frame defining at least one opening arranged on a plane;
at least one sub-mask overlapping the opening, and defining holes through which a deposition material is able to pass; and
an aligner between the sub-mask and the body frame, and configured to move the sub-mask within the opening in response to applied voltages.

2. The mask of claim 1, wherein the sub-mask has a polygonal shape comprising sides, and
wherein the aligner comprises actuators between the sides of the sub-mask and the body frame.

3. The mask of claim 2, wherein the sub-mask comprises connecting parts protruding from the sides and contacting the actuators.

4. The mask of claim 2, wherein the actuators comprise a first electrode contacting the body frame, a second electrode contacting the sub-mask, and a piezoelectric layer between the first electrode and the second electrode.

5. The mask of claim 4, wherein the piezoelectric layer is configured to vibrate according to an applied voltage.

6. The mask of claim 5, wherein at least one of the actuators has a shape configured to be changed by vibration of the piezoelectric layer, and
wherein the sub-mask is configured to be moved by the at least one of the actuators having the changed shape.

7. The mask of claim 6, wherein the sub-mask is horizontally moved or rotated in a direction parallel to the plane by the at least one of the actuators having the changed shape.

8. The mask of claim 2, wherein, in an area where the sub-mask and the body frame are spaced apart from each other in a first direction, the actuators comprise a first actuator extending in a second direction crossing the first direction.

9. The mask of claim 8, wherein, in an area where the sub-mask and the body frame are spaced apart from each other in the second direction, the actuators comprise a second actuator extending in the first direction.

10. The mask of claim 9, wherein the first actuator comprises a first portion, a second portion, and a third portion sequentially arranged in a direction opposite to the second direction,
wherein the sub-mask comprises a connecting part protruding from one of the sides in the first direction, and contacting the first portion, and
wherein the body frame comprises a fixing part protruding in a direction opposite to the first direction, and contacting the third portion.

11. The mask of claim 10, wherein the third portion is fixed by the fixing part, and
wherein the first actuator is bent clockwise or counterclockwise around the third portion to move the sub-mask.

12. A deposition apparatus comprising:
a chamber;
a deposition source inside the chamber, and configured to supply a deposition material;
a support configured to fix a substrate on the deposition source;
a mask comprising a body frame defining at least one opening arranged on a plane, at least one sub-mask overlapping the opening and defining holes through which the deposition material is able to pass, and an aligner between the sub-mask and the body frame and configured to move the sub-mask within the opening in response to applied voltages; and
a mask frame supporting the mask.

13. The deposition apparatus of claim 12, wherein the mask comprises a first alignment mark, and
wherein the support comprises a second alignment mark corresponding to the first alignment mark.

14. The deposition apparatus of claim 13, further comprising:
a camera for capturing an image of the first and second alignment marks; and
a processor for aligning a position of the sub-mask based on the image.

15. The deposition apparatus of claim 14, further comprising a voltage applier for applying a voltage to the aligner according to a control signal generated by the processor.
